(19) United States
(12) Patent Application Publication
(10) Pub. No.: US 2006/0276001 A1
(43) Pub. Date: Dec. 7, 2006

(54) Method for manufacturing a semiconductor device having a STI structure

(75) Inventor: Kazuo Ogawa, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY INC., Tokyo (JP)

(21) Appl. No.: 11/446,181

(22) Filed: Jun. 5, 2006

(30) Foreign Application Priority Data
Jun. 6, 2005 (JP) 2005-165370
Apr. 20, 2006 (JP) 2006-116537

(51) Int. Cl. H01L 21/76

(52) U.S. Cl. 438/424

(57) ABSTRACT

A method for manufacturing a STI structure includes the steps of anisotropic-etching the surface of a silicon substrate to form a trench, forming a first thermal oxide film on the surface of the trench at a substrate temperature of 1000 degrees C. or above, removing the first oxide film, anisotropic-etching the bottom of the trench to increase the depth of the trench, forming a second oxide film on the surface of the trench, and embedding an insulator in the trench.

### BACKGROUND OF THE INVENTION

(a) Field of the Invention

The present invention relates to a method for manufacturing a semiconductor device having a STI (shallow trench isolation) structure and, more particularly, to the improvement of STI structure. The present invention also relates to a method for manufacturing a semiconductor device having a recessed channel array transistor.

(b) Description of the Related Art

A STI structure is increasingly used for electric isolation of the surface region of a semiconductor substrate in a semiconductor device such as including bipolar and MOS transistors. The STI structure is such that an insulator is embedded in a trench formed on a semiconductor substrate (silicon substrate) for isolation between adjacent device areas.

Upon forming the STI structure on a silicon substrate, the surface of the silicon substrate is subjected to an anisotropic etching process to form thereon a trench, the surface of which is then covered with a thin thermal oxide film by using a thermal oxidation technique. The internal of the trench is then filled with an insulator deposited on the thermal oxide film. The thermal oxide film is formed so as to remove the damage caused by the anisotropic etching on the surface of the trench, recover a smooth surface for the trench and reduce the interface state thereof.

The thermal oxidation process for forming the thermal oxide film on the trench surface is generally conducted under the ambient oxygen gas or steam used as an oxidizing species. In such an oxidation, the characteristic of the resultant oxide film differs depending on the substrate temperature being higher or lower than 1000 degrees C., over which the silicon substrate or oxide film assumes a viscosity or fluidity. In the conventional techniques using either the lower-temperature oxidation conducted below 1000 degrees C. or the higher-temperature oxidation conducted above 1000 degrees C., there are following respective problems.

FIG. 4A shows the situation involved with the lower-temperature oxidation, wherein an etching mask 14 including a pad oxide film 12 and a pad nitride film 13 is used for the anisotropic etching for forming the trench. An oxide film 16 is formed on the surface of the trench by the thermal oxidation process conducted after the anisotropic etching. Since the lower-temperature oxidation provides no viscosity or fluidity for the silicon substrate and oxide film, the trench 15 has a sharp contour at the top edge 17A thereof, whereby a suitable top edge, i.e., a smooth top edge or a large curvature radius cannot be obtained.

The sharp contour at the top edge 17A of the trench surface causes the thickness of the gate oxide film (not shown) formed in the vicinity of the trench 15 to be locally smaller than usual, thereby degrading the reliability of the gate oxide film. For example, a MOSFET including such a gate oxide film having a locally smaller thickness is liable to an electric-field concentration at the small-thickness portion of the gate oxide film. This may cause a hump on a gate voltage-drain current characteristic curve in a sub-threshold region of the MOSFET such as shown in FIG. 5, wherein graph (i) shows a normal curve and graph (ii) shows the hump caused by the electric-field concentration. The hump may prevent the normal operation of the MOSFET.

On the other hand, the higher-temperature oxidation may involve a facet through which the silicon crystal surface is exposed, without causing the sharp edge 17A as encountered in the lower-temperature oxidation. FIG. 4B shows the facet 19 formed at the bottom corner of the trench 15 by the high-temperature oxidation. The facet 19 is likely to be subjected to a stress concentration, which may generate a crystal defect having a start point thereat during an ion implantation, oxidation or thermal process performed after the formation of the STI structure. The crystal defect, if formed, will increase the junction leakage current across the p-n junction in the MOSFET, thereby degrading the product yield of the MOSFETs. On the other hand, the lower-temperature oxidation does not provide a viscosity or fluidity for the silicon and oxide film, whereby the trench will have a round contour 18 shown in FIG. 4A at the bottom corner of the trench 15.

Since the facet is formed due to the surface orientation dependence of the oxidation rate, the facet is more likely to occur in the lower temperature range in which the oxide film generally has a larger surface orientation dependence. However, in the lower-temperature oxidation of the silicon, since the silicon and oxide film do not have a viscosity or fluidity, the surface orientation dependence of the oxidation rate is suppressed to thereby result in absence of the facet. More specifically, the facet will be formed by the viscosity or fluidity of the silicon and oxide film generated in a specific condition of the higher-temperature oxidation process in which the surface orientation dependence of the oxidation occurs or develops.

As described above, in the conventional fabrication technique for the semiconductor device, it is difficult to suppress occurrence of the facet at the bottom corner of the trench and to obtain the smooth top edge thereof at the same time, whereby reduction in the junction leakage current and improvement in the reliability of the gate oxide film are incompatible in a MOSFET, for example.

Patent Publication JP-2001-210719A describes a technique using both the higher-temperature and lower-temperature oxidation steps. In this technique, a higher-temperature oxidation is first conducted for forming a first oxide film on the surface of the trench after forming the trench on the silicon substrate. The first oxide film is then removed, and a second oxide film is then formed on the surface of the trench by using a lower-temperature oxidation. It is recited in the publication that the removal of the first oxide film followed by formation of the second oxide film by using the lower-temperature oxidation reduces the stress on the bottom of the trench.

It was found by the inventor that the facet formed in the higher-temperature oxidation in the STI structure described in the above publication is not always eliminated by the removal of the first oxide film followed by the lower-temperature oxidation. The facet remaining on the bottom corner of the trench causes a crystal defect resulting from the stress and thus involves occurrence of the junction leakage current.

### SUMMARY OF THE INVENTION

In view of the above problems in the conventional techniques, it is an object of the present invention to provide a method for forming a semiconductor device having a STI structure, which is capable of suppressing the facet and achieving a smooth top edge in the trench to obtain both reduction in the junction leakage current and improvement in the reliability of the gate oxide film.

It is another object of the present invention to provide a semiconductor device having a recessed channel array transistor having an improved transistor characteristic.

The present invention provides a method for manufacturing a semiconductor device including the steps of: etching a silicon substrate by a first anisotropic etching process using a mask pattern to thereby form a trench on a surface of the silicon substrate; forming a first oxide film on a surface of the silicon substrate including a surface of the trench by using a first thermal oxidation process at a substrate temperature of not lower than 1000 degrees C.; removing the first oxide film from the surface of the trench; and etching at least a bottom of the trench by a second anisotropic etching process using the mask pattern to thereby increase a depth of the trench.

In accordance with the method of the present invention, the first thermal oxidation process performed at a substrate temperature of not lower than 1000 degrees C. prevents a sharp top edge from being formed in the trench to obtain a smooth contour thereof. This provides a sufficient thickness of the first oxide film on the top edge of the trench, and thus suppresses electric field concentration on the top edge of the trench. On the other hand, the facet formed by the first thermal process at a substrate temperature of not lower than 1000 degrees C. is removed by the second anisotropic etching process which increases the depth of the trench, whereby occurrence of a crystal defect starting from the facet on the bottom corner of the trench can be suppressed, thereby suppressing the increase in the junction leakage current.

It is preferable in the present invention that the following relationship:
tₒₓ<2d·sin θ/cos² θ
hold, where θ, d, tₒₓ are taper angle of the sidewall of the trench with respect to a perpendicular to the main surface of the silicon substrate, depth of the trench measured from the main surface of the silicon substrate, and thickness of the first oxide film, respectively. By employing such a condition wherein a facet is not formed outside the opening of the mask pattern, the facet can be substantially completely removed during the second anisotropic etching conducted for increasing the depth of the trench.

It is also preferable that the thermal oxidation process uses oxygen gas or steam as an oxidizing species. Suppression of oxidation of the nitride film, if used therein, prevents reduction in the reliability of the gate oxide film caused by a white ribbon as will be described later.

It is also preferable that the method further include, subsequent to the second anisotropic etching step, the step of forming a second oxide film on the surface of the trench. The process for forming the second oxide film at a substrate temperature of lower than 1000 degrees C. removes the damage on the surface of the trench caused by the second anisotropic etching, recovers a smooth surface on the bottom surface of the trench, and thus reduces the interface state thereof. The first and/or second thermal oxidation step may use oxygen or steam as an oxidizing species.

It is also preferable that the method further includes the step of embedding an insulator in the trench with an intervention of the second oxide film, to thereby form a STI structure. The STI structure may be used for isolation of the substrate into a plurality of device areas. In this case, the trench provides a higher reliability for the gate oxide film near the top edge of the trench, and suppresses the junction leakage current caused by the crystal defect formed on the bottom corner of the trench.

In an alternative, the method may further include the steps of: removing the mask pattern, the first oxide film outside the trench, and the second oxide film; forming a third oxide film on the surface of the silicon substrate including the surface of the trench by using a second thermal oxidation process at a substrate temperature of not higher than 1000 degrees C.; and forming a conductor film on the third oxide film while embedding the conductor film in the trench. In this case, the method may further include the step of patterning the conductive film to form gate electrodes. A semiconductor device having a recessed channel array transistor is formed in which a gate oxide film has a higher reliability near the top edge of the trench, and a crystal defect at the bottom corner of the trench is suppressed.

The above and other objects, features and advantages of the present invention will be more apparent from the following description, referring to the accompanying drawings.

### BRIEF DESCRIPTION OF THE DRAWINGS

FIGS. 1A to 1H are sectional views showing consecutive steps of manufacturing a semiconductor device according to a first embodiment of the present invention.

FIG. 2 is a sectional view showing the final structure of the STI structure manufactured by the first embodiment.

FIG. 3 shows a detailed sectional view showing a portion of the STI structure shown in FIG. 2.

FIGS. 4A and 4B are sectional views showing the trench structure obtained by a lower-temperature oxidation and a higher-temperature oxidation, respectively.

FIG. 5 is a graph showing the gate voltage-drain current characteristic of a MOSFET.

FIGS. 6A to 6H are sectional views showing consecutive steps of manufacturing a semiconductor device according to a second embodiment of the present invention.

### PREFERRED EMBODIMENT OF THE INVENTION

Now, the present invention is more specifically described with reference to accompanying drawings, wherein similar constituent elements are designated by similar reference numerals throughout the drawings.

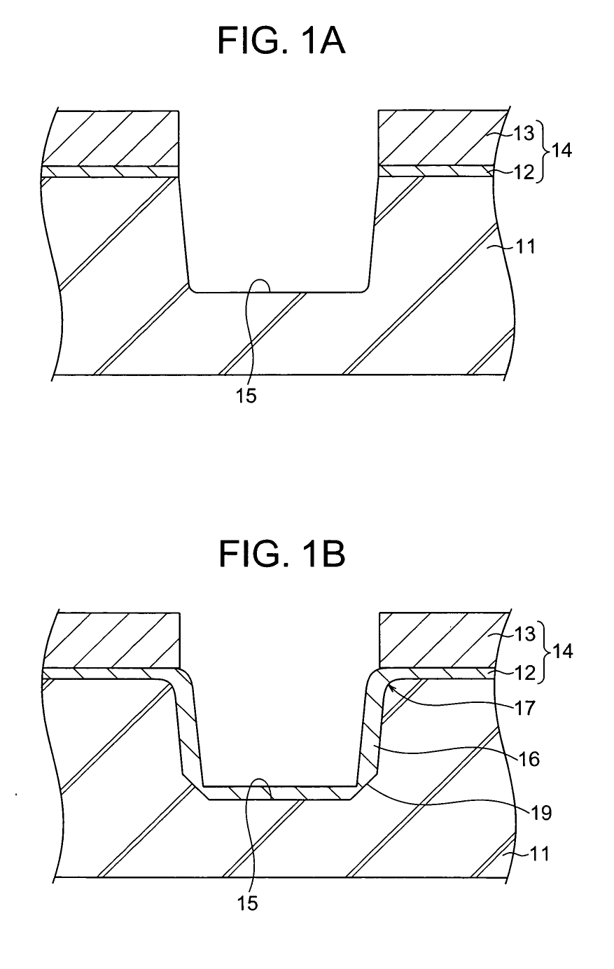

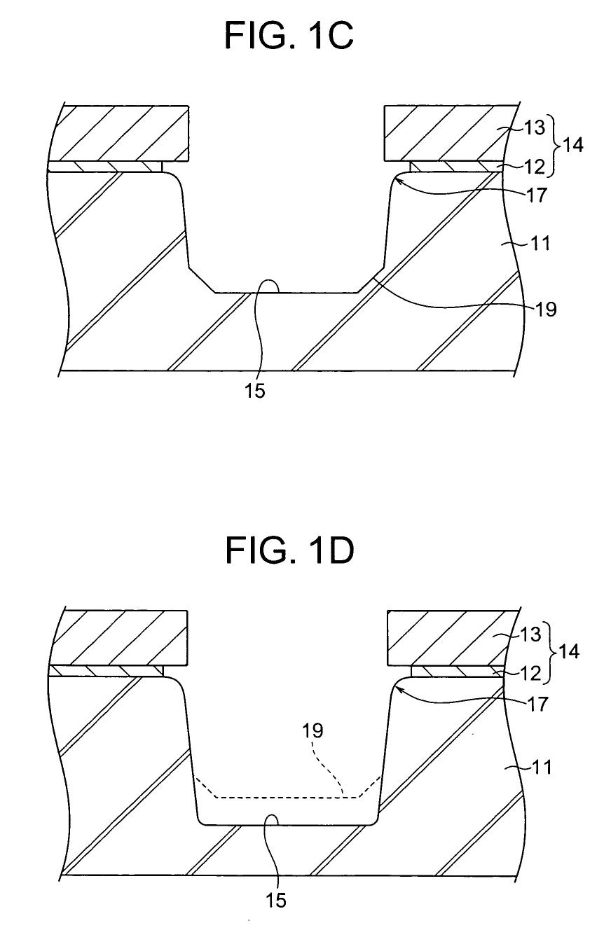

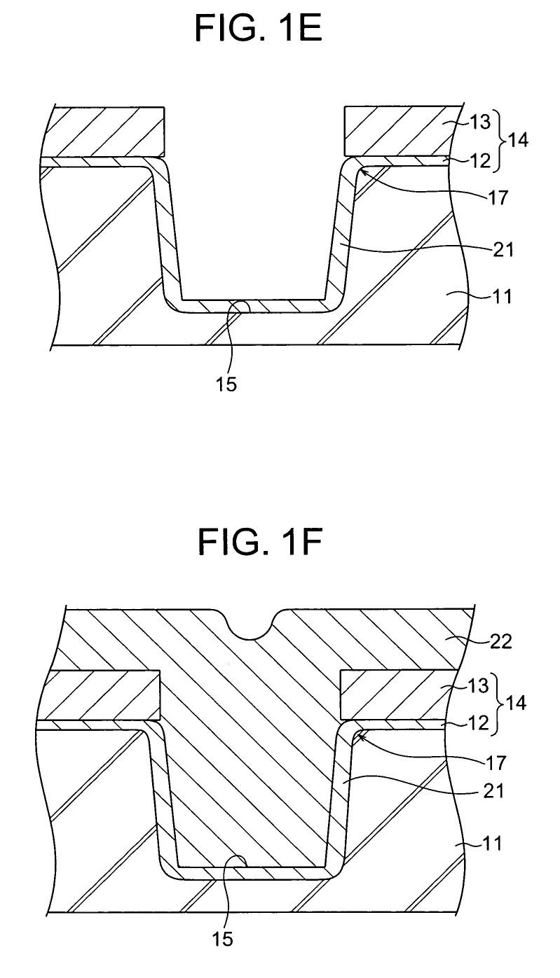

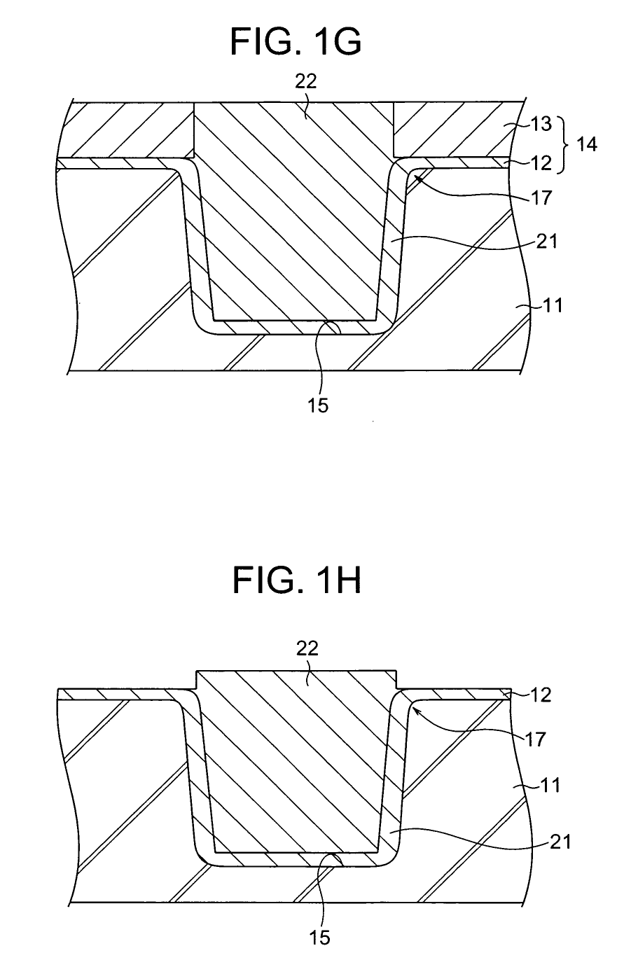

FIGS. 1A to 1H are sectional views showing consecutive steps of manufacturing a semiconductor device according to a first embodiment of the present invention. First, an about 10-nm-thick pad oxide film 12 made of silicon oxide and an about 150-nm-thick pad nitride film 13 made of silicon nitride are consecutively formed on a silicon substrate 11. Subsequently, by using a known technique, the pad nitride film 13 and pad oxide film 12 are etched to form a combination mask 14 having a desired opening pattern. Then, a first anisotropic etching process is conducted using the mask 14 as an etching mask, to form a trench 15 having a depth of 200 nm as measured from the top surface of the silicon substrate 11, thereby obtaining the structure shown in FIG. 1A.

The first anisotropic etching process is conducted in an etching gas including O₂, HBr and Cl₂ and at a gas pressure of 10 to 50 Torr. The taper angle of the sidewall of the trench 15 with respect to a perpendicular to the main surface of the silicon substrate is generally 5 to 10 degrees, and in this example, it is set at 5 degrees. The taper angle may be controlled by selecting the flow rate of the etching gas and the substrate temperature during the etching process. For example, a higher flow rate of O₂ will increase the taper angle, whereas a higher flow rate of HBr will reduce the taper angle. In addition, a higher substrate temperature during the etching will decrease the taper angle.

Thereafter, the surface of the trench 15 is oxidized at a substrate temperature of 1000 degrees C. or above, to thereby form a first oxide film 16 on the surface of the trench 15, as shown in FIG. 1B. Examples of the oxidizing species in this oxidation include oxygen. In the oxidizing process for forming the first oxide film 16, a facet 19 is formed on the bottom corner of the trench 15 due to the higher temperature.

In the higher-temperature oxidation process, the first oxide film 16 should preferably have a thickness of 10 nm or above, and more preferably 30 nm or above, in order for forming a smooth top edge 17 of the trench 15. The substrate temperature may be preferably 1100 degrees C. or above to obtain a sufficient viscosity or fluidity of the silicon or oxide film.

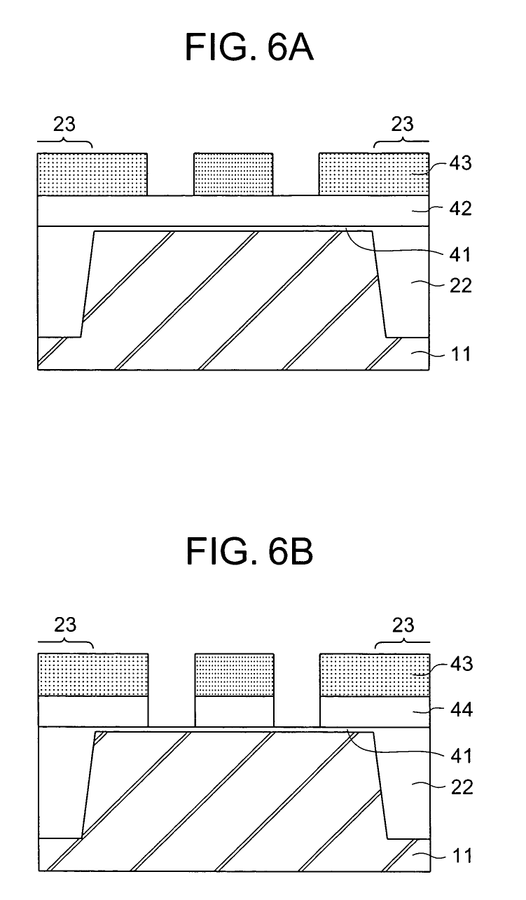

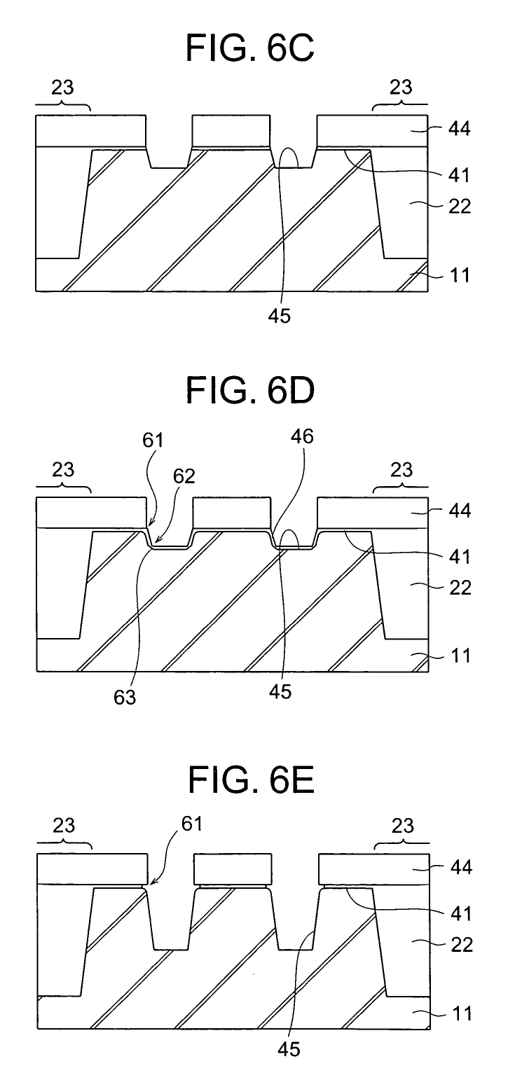

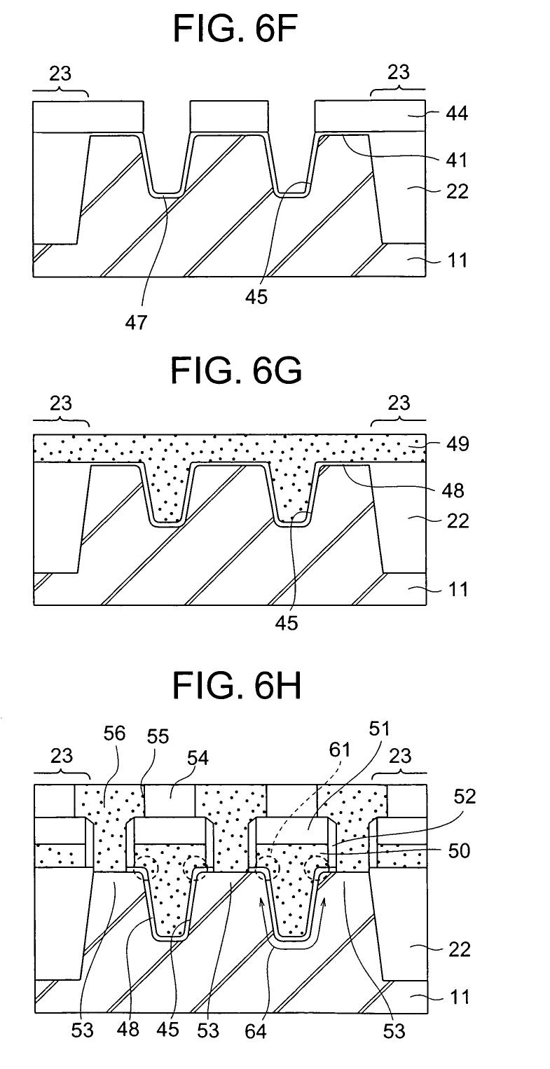

In the higher-temperature oxidation, the thickness of the first oxide film 16 should be determined such that the facet 19 is completely removed by a later second anisotropic etching. FIG. 3 schematically shows an enlarged view of a portion of the trench shown in FIG. 1B. In FIG. 6, numerals 31, 32, 33 and 34 denote the top of the first oxide film 16, the bottom surface of the trench 15 before the higher-temperature oxidation, the bottom surface of the first oxide film 16 and a vertical plane passing through the top edge 35 of the trench 15. Signs tₒₓ, d and θ represent the thickness of the first oxide film, the depth of the trench 15 as measured from the main surface (reference surface) of the silicon substrate 11 and the taper angle of the sidewall of the trench 15.

The oxide film formed by a thermal oxidation generally has a volume double the volume of the original silicon before the thermal oxidation. Accordingly, the distance D1 shown in FIG. 6 is equal to tₒₓ/2. In order for completely removing the facet 19, the facet 19 should not be formed outside the vertical plane 34, namely, in the area covered by the silicon nitride film 13 during the second anisotropic etching. For this purpose, the distance D1 should be smaller than the length (distance) D2 of the perpendicular from a point P on the plane 34 to the bottom 36 of the sidewall of the trench 15.

Assuming that the depth of the point P measured from the reference surface is d′, the depth d′ is expressed by d/cos² θ, and thus the length D2 is expressed by d sin θ/cos² θ. From the desired relationship D1<D2, a relationship tₒₓ<2d sin θ/cos² θ can be obtained. In the present embodiment, since the taper angle θ is 5 degrees and the depth of the trench 15 is 200 nm, the maximum of the thickness tₒₓ is determined at 35 nm. In an alternative, the relationship may be tₒₓ<2d sin θ which satisfies a more strict condition.

Subsequent to forming the first oxide film 16, a wet etching is conducted using dilute hydrofluoric acid as an etchant to remove the first oxide film 16, as shown in FIG. 1C. In order for completely removing the first oxide film 16, the amount of etching should be determined at 120 to 150% of the thickness of the first oxide film 16 in this wet etching. The wet etching process removes the first oxide film 16 and a portion of the pad oxide film 12 exposed from the trench 15, thereby exposing a silicon surface having a smooth contour on the top edge 17 of the trench 15. In addition, the facet 19 is exposed at the bottom corners of the trench 15. In an alternative, a dry etching technique allowing a higher isotropy and a higher selectivity may be used for removing the first oxide film 16.

Subsequently, as shown in FIG. 1D, the second anisotropic etching process is conducted using the mask 14 as an etching mask, to etch the bottom of the trench 15 and the vicinity thereof. The amount of etching by the second anisotropic etching process is determined so that the facet 19 is completely removed, and is determined at 50 nm in this embodiment. After the second anisotropic etching, the depth of the trench 15 is increased up to 250 nm. In FIG. 1D, the bottom of the trench 15 before the second anisotropic etching process is expressed by a dotted line. A preferred depth after the second dry etching process is generally between 200 nm and 300 nm.

Subsequently, a lower-temperature thermal oxidation is conducted at a substrate temperature below 1000 degrees C. to oxidize the surface of the trench 15, thereby forming a second oxide film 21 as shown in FIG. 1E. Examples of the oxidizing species in the lower-temperature thermal oxidation include oxygen. The formation of the second oxide film 21 is conducted to remedy the damage caused by the second anisotropic etching on the silicon surface of the trench 15, thereby recovering the smooth surface. In addition, the second oxide film prevents the insulator material to be embedded in the trench 15 from contaminating the surface of the silicon substrate 11. The second oxide film 21 has a thickness of 5 nm or above, and may preferably have a thickness of 20 nm.

In the lower-temperature thermal oxidation process, the substrate temperature may preferably be 900 degrees C. or below, to suppress the viscosity or fluidity of the silicon and oxide film and thus suppress occurring of the facet. Instead of the lower-temperature thermal oxidation, the second oxide film may be formed by a CVD (chemical vapor deposition) process at a substrate temperature below 1000 degrees C. However, the thermal oxidation is more preferable, because the thermal oxidation significantly reduces the density of interface state between the silicon substrate 11 and the second oxide film 21.

Subsequently, an insulator material 22 is deposited using a known CVD technique in the trench 15 and on the mask 14, as shown in FIG. 1F, followed by a CMP (chemical-mechanical polishing) process for planarization, to polish the insulator film 22 while using the pad nitride film 13 as a CMP stopper layer, as shown in FIG. 1G.

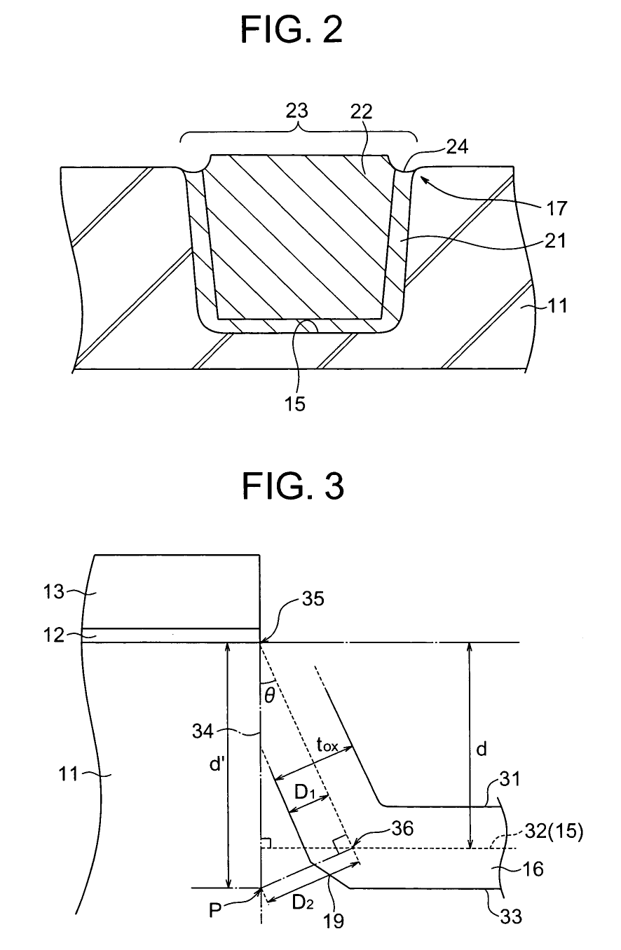

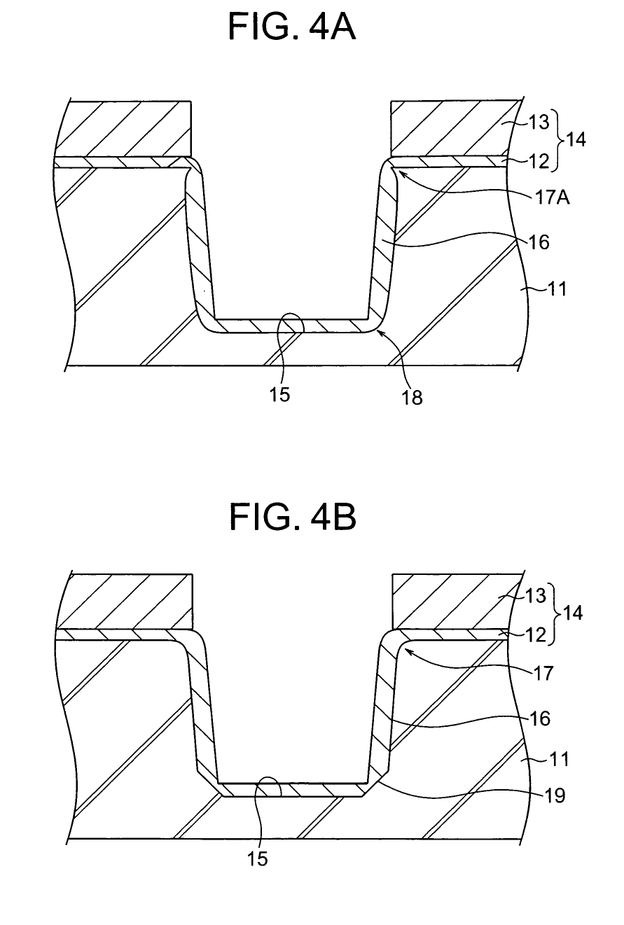

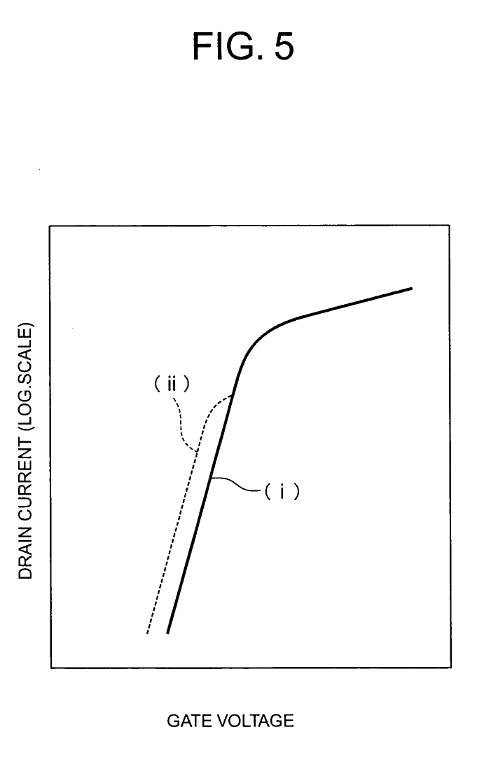

Subsequently, a wet etching process is conducted using heated phosphoric acid as an etchant to remove the pad nitride film 13, as shown in FIG. 1H, followed by another wet etching process using dilute hydrofluoric acid as an etchant, to remove the pad oxide film 12, whereby an STI structure is obtained, as shown in FIG. 1H. After these wet etching processes, as shown in FIG. 2 showing the final STI structure, a divot is formed on the exposed edge of the second oxide film 21 because those etchings proceed in both the longitudinal and lateral directions.

Thereafter, the exposed surface of the silicon substrate 11 are oxidized to form a gate oxide film (not shown) on the first and second oxide films 21 and 22, followed by forming diffused regions, gate electrodes and interconnect lines overlying the silicon substrate 11, to obtain a final product of the semiconductor device.

In the configuration of the present embodiment, the facet 19 formed during formation of the first oxide film 16 is substantially completely removed by the second anisotropic etching process. In addition, the lower-temperature thermal oxidation at a substrate temperature of 900 degrees C. suppresses occurring of the facet at the bottom corner of the trench after the bottom extension of the trench. Thus, suppression of the crystal defect and thus the suppression of the junction leakage current can be obtained in the present embodiment. The higher-temperature thermal oxidation at a substrate temperature of 1100 degrees C. for achieving a thickness of 30 nm for the thermal oxide film allows the top edge of the trench to have a smooth contour having a large curvature radius, whereby degradation in the reliability of the gate oxide film can be suppressed to thereby assure normal operation of the resultant MOSFET.

In the method of the present embodiment, a divot 24 may be formed on the top edge of the trench 15, as shown in FIG. 2, and will not cause degradation in the characteristic of the gate oxide film because the top edge of the trench 15 has a large curvature radius and a smooth top edge 17.

The present inventor conducted an experiment applying the technique described in U.S. Pat. No. 6,037,273 on a thermal oxidation of the trench surface. This technique uses radicals as oxidizing species. The experiment revealed that a facet is not formed at the bottom corner of the trench and yet the trench has a smooth top edge.

However, the radicals having a higher oxidizing ability oxidized the nitride film as well as the oxide film, to generate an excessive amount of oxynitride, which formed as an oxynitride film called as a “white ribbon” on the silicon substrate. The white ribbon prevents oxidation of the silicon surface during formation of the gate oxide film, thereby degrading the characteristic of the gate oxide film. In addition, the thermal oxidation process using the radicals generally raises the cost of the oxidation compared to an ordinary thermal oxidation. In view of the above, the thermal oxidation for forming the STI structure should preferably use an ordinary thermal oxidation process using oxygen gas or steam as the oxidizing species.

FIGS. 6A to 6E show consecutive steps of manufacturing a semiconductor device according to a second embodiment of the present invention. In this embodiment, the present invention is applied to a process for forming a gate electrode in a recessed channel array transistor. In the recessed channel array transistor, the gate electrode of a MOSFET has a portion received in a trench formed on the surface region of the silicon substrate, whereby the channel of the MOSFET extends along the bottom surface region of the trench to have a larger channel length.

A device isolation structure 23 is first formed on the surface region of a silicon substrate 11, followed by a thermal oxidation process to form an about 10-nm-thick protective oxide film 41 on the device region of the silicon substrate 11. Thereafter, a nitride film 42 is deposited to a thickness of 100 nm on the protective oxide film 41 by a CVD process. The protective oxide film 41 is formed to intervene in the direct contact between the silicon substrate 11 and the nitride film 42, and to protect the silicon substrate 11 against the heated phosphoric acid used in a wet etching process. Thereafter, a photoresist mask 43 is formed on the nitride film 42 by a known photolithographic process, as shown in FIG. 6A, followed by an etching process to pattern the nitride film 42 by using the resist mask 43, thereby forming a hard mask 44, as shown in FIG. 6B.

Subsequently, a first anisotropic etching process is conducted using the hard mask 44, to form a trench 45 on the silicon substrate 11, as shown in FIG. 6C. Thereafter, a higher-temperature thermal oxidation process is conducted at a substrate temperature of 1000 degrees C. or above, to oxidize the surface of the trench 45 and form a first oxide film 46 on the surface of the trench 45, as shown in FIG. 6D. In order for obtaining a smooth surface at the top edge of the trench 45 during the higher-temperature thermal oxidation, the first thermal oxide film 46 preferably has a thickness of 10 nm or above. The higher-temperature oxidation process may form a facet 63 on the bottom corner of the trench.

Thereafter, a wet etching process is conducted to remove the first oxide film 46, thereby exposing a smooth silicon surface at the top edge of the trench 45. The facet 63 is thus exposed on the bottom corner of the trench 45. Subsequently, a second anisotropic etching process is conducted using the hard mask 44, to etch the bottom of the trench 45 and the vicinity thereof and thus remove the facet 63, as shown in FIG. 6E.

Thereafter, a lower temperature thermal oxidation process is conducted at a substrate temperature below 1000 degrees C., to oxide the surface of the trench 45 and thus form a second oxide film 47 thereon, as shown in FIG. 6F. The second oxide film 47 is formed to remedy the damage caused by the second anisotropic etching process on the surface of the trench 45, and thus to recover a smooth surface. The second oxide film 47 also protects the silicon substrate 11 against heated phosphoric acid used in a wet etching process. The lower-temperature thermal oxidation process for forming the second oxide film 47 will not involve a facet at the bottom corner of the trench 45, and maintains the smooth surface at the top edge of the trench 45.

Thereafter, a wet etching process is conducted using heated phosphoric acid as an etchant to remove the hard mask 44. During the removal of the hard mask 44, the protective oxide film 41 and second oxide film 47 protect the surface of the silicon substrate 11 against the etchant as described before. After removing the protective oxide film 41 and second oxide film 47, a lower-temperature oxidation process is conducted at a substrate temperature below 1000 degrees C., to thereby form a gate oxide film 48 on the surface of the silicon substrate 11 including the surface of the trench 45. Further, a conductive material 49 including impurity-doped polysilicon is deposited on the surface of the silicon substrate 11 to fill the internal the trench 45 via the gate oxide film 48 for forming a gate electrode layer, as shown in FIG. 6G.

A nitride film is then deposited on the impurity-doped polysilicon 49, followed by patterning the nitride film and impurity-doped polysilicon 49, to form the gate electrode 50 and gate spacer 51, which are consecutively formed on the gate oxide film 48. In this patterning, the gate electrode 50 is left in the internal of the trench 45. An insulating film is then formed on the exposed gate electrode 50, gate spacer 51 and gate oxide film 48, followed by etch back thereof and of the gate oxide film 48, to leave a sidewall protective film 52 on the sidewall of the gate electrode 50 and gate spacer 52.

Thereafter, an ion implantation process is conducted using the gate spacer 51 and the sidewall protective film 52 as a mask, to thereby form diffused regions 53 in the silicon substrate on both sides the gate electrode 50. Thus, recessed channel array transistor is obtained including the gate electrode 50 formed in the internal of the trench and on the silicon substrate 11, and diffused regions 53 formed in the silicon substrate 11 on both sides of the gate electrode 50.

Thereafter, an interlevel dielectric film 54 is deposited on the silicon substrate 11, the gate spacer 51 and sidewall protective film 52, and is patterned by etching to form therein contact holes 55 between adjacent gate electrodes 50. The patterning for forming the contact holes 55 is conducted using the gate spacer 51 and sidewall protective film 42 as a mask in a self-alignment technique. Subsequently, a conductive material is embedded in the contact holes 55 by using a known technique to form contact plugs 56 therein, as shown in FIG. 6H. Further, a bottom electrode of the capacitor in contact with the top of the contact plug 56, a capacitor insulation film and a top electrode as well as overlying interconnect lines are formed to obtain a DRAM device configuring a semiconductor device.

In a normal planar transistor, if the width of the gate electrode is reduced together with development of finer dimensions of the semiconductor device, the gate length is reduced in proportion to the reduction of the gate electrode width, to cause a short-channel effect therein wherein the threshold voltage is reduced. The reduction of the threshold voltage, which involves degradation of the transistor characteristics, is suppressed heretofore by increasing the impurity concentration of the diffused regions. However, a higher impurity concentration in the diffused regions increases the electric field across the p-n junction to increase the junction leakage current, involving a problem of reduction in the data retention capability.

On the other hand, in the recessed channel array transistor as described above, the channel having a detour path along the bottom of the trench 45 has a larger channel length or gate length for a given occupied area compared to the normal planar transistor. Thus, the resultant memory cell has a higher data retention rate by maintaining a lower impurity concentration in the diffuse regions to thereby reduce the electric field across the p-n junction.

In the conventional technique for manufacturing the recessed channel array transistor, however, since the gate oxide film is generally formed on the surface of the silicon substrate including the trench by a lower-temperature thermal oxidation at a substrate temperature lower than 1000 degrees C., the trench may have a sharp top edge to thereby reduce the thickness of the gate oxide film and degrade the transistor characteristics. The lower-temperature thermal oxidation process is employed herein for preventing the facet on the bottom corner of the trench and thus preventing occurrence of the crystal defect.

The method for forming the recessed channel array transistor according to the above embodiment employs a higher-temperature thermal oxidation at a substrate temperature of 1000 degrees C. or above for forming the first oxide film having a thickness of 10 nm or above. This provides a smooth contour on the top edge of the trench, allowing the gate oxide film formed later to have a sufficient thickness and thus preventing electric field concentration. It is to be noted that the facet formed on the bottom corner of the trench by the higher-temperature thermal oxidation is removed by the second anisotropic etching for increasing the depth of the trench in the present embodiment.

The recessed channel array transistor formed in a DRAM is first disclosed by J. K., Kim from Samsung Co. Ltd., on a literature “The Breakthrough in data retention time for DRAM using Recess-Channel-Array Transistor (RCAT)” for 88th feature size and beyond, 2003 Symposium on VLSI Technology Digest of Technical Papers.

Since the above embodiments are described only for examples, the present invention is not limited to the above embodiments and various modifications or alterations can be easily made therefrom by those skilled in the art without departing from the scope of the present invention.

What is claimed is:

1. A method for manufacturing a semiconductor device comprising the steps of:
etching a silicon substrate by a first anisotropic etching process using a mask pattern to thereby form a trench on a surface of said silicon substrate;
forming a first oxide film on a surface of said silicon substrate including a surface of said trench by using a first thermal oxidation process at a substrate temperature of not lower than 1000 degrees C.;
removing said first oxide film from the surface of said trench; and
etching at least a bottom of said trench by a second anisotropic etching process using said mask pattern to thereby increase a depth of said trench.

2. The method according to claim 1, wherein the following relationship:
tₒₓ<2d·sin θ/cos² θ
holds, where θ, d, tₒₓ are taper angle of a sidewall of said trench with respect to a perpendicular to a main surface of said silicon substrate, depth of said trench measured from the main surface of said silicon substrate, and thickness of said first oxide film, respectively.

3. The method according to claim 1, wherein said thermal oxidation uses oxygen or steam as an oxidizing species.

4. The method according to claim 1, further comprising, subsequent to said second anisotropic etching step, the step of forming a second oxide film on the surface of said trench by using a second thermal oxidation process at a substrate temperature of lower than 1000 degrees C.

5. The method according to claim 4, wherein said second oxide film forming step uses oxygen or steam as an oxidizing species.

6. The method according to claim 4, further comprising, subsequent to said second oxide film forming step, the step of embedding an insulator in said trench with an intervention of said second oxide film.

7. The method according to claim 4, further comprising, subsequent to said second oxide film forming step, the steps of:
removing said mask pattern, said first oxide film outside said trench, and said second oxide film;
forming a third oxide film on the surface of said silicon substrate including the surface of said trench by using a second thermal oxidation process at a substrate temperature of not higher than 1000 degrees C.; and
forming a conductor film on the surface of said silicon substrate while embedding said conductor film in said trench.

8. The method according to claim 7, further comprising, subsequent to said conductor film forming step, the step of patterning said conductive film to form gate electrodes.
